(19) United States
(12) Patent Application Publication
(10) Pub. No.: US 2013/0099267 A1
(43) Pub. Date: Apr. 25, 2013

(54) LIGHT EMITTING DEVICE PACKAGE AND MANUFACTURING METHOD THEREOF

(71) Applicant: Samsung Electronics Co., Ltd., Suwon-si (KR)

(72) Inventors: Jae Wook JANG, Seongnam-si (KR); Seung Yoon CHOI, Suwon-si (KR)

(73) Assignee: SAMSUNG ELECTRONICS CO., LTD., Suwon-si (KR)

(21) Appl. No.: 13/656,783

(22) Filed: Oct. 22, 2012

(30) Foreign Application Priority Data
Oct. 21, 2011 (KR) 10-2011-0108072

(51) Int. Cl. H01L 33/62; H01L 33/60

(52) U.S. Cl. 257/98; 257/99; 438/26; 257/E33.057; 257/E33.072

(57) ABSTRACT

A light emitting device (LED) package and a manufacturing method thereof are provided. The LED package may include a package body including a cavity, a first lead frame and a second lead frame that are disposed in the cavity of the package body, and an LED mounted on a bottom surface of the cavity of the package body, the LED including a transparent substrate, a first semiconductor layer, an active layer, and a second semiconductor layer that are laminated sequentially in one of a first direction that is parallel to the bottom surface of the cavity and a second direction that is inclined with respect to the bottom surface of the cavity.

### CROSS-REFERENCE TO RELATED APPLICATION

This application claims priority from Korean Patent Application No. 10-2011-0108072, filed on Oct. 21, 2011 in the Korean Intellectual Property Office, the disclosure of which is incorporated herein by reference.

### BACKGROUND

1. Field

Apparatuses and methods consistent with exemplary embodiments relate to a light emitting device (LED) package and a manufacturing method thereof, and more particularly, to an LED package and a manufacturing method thereof that may improve a light extraction efficiency and may reduce heat temperature of an LED.

2. Description of the Related Art

An LED is a semiconductor device that may realize light of various colors by forming a light emitting source by changing a material of a compound semiconductor, for example, gallium arsenide (GaAs), aluminum gallium arsenide (AlGaAs), gallium nitride (GaN), indium gallium indium phosphide (InGaInP), and the like.

Recently, an LED is being produced as a product with high luminance and high quality, as opposed to a general-purpose product with low luminance. Also, with a realization of a high-property blue and white LED, an application of the LED is extended to a display, next generation lighting, and the like. Generally, an LED is manufactured in a form of a package.

FIG. 1 is a cross-sectional view of a structure of an LED package 10 according to the related art. Referring to FIG. 1, the LED package 10 may include a package body 11, a first lead frame 12, a second lead frame 13, an LED 14, and a transparent resin unit 15.

The package body 11 may include a cavity 11a, and the LED 14 may be mounted in the cavity 11a. Light generated in an inner portion of the LED 14 may be directed along three paths.

In particular, a light may be directed towards an upper portion of the LED 14 along a first path L₁. In a case of the first path L₁, the light may be emitted from the LED 14, and may be transmitted to an external environment through the transparent resin unit 15.

Another light may be directed towards a lower portion of the LED 14, be reflected by a bottom surface of the cavity 11a, and be directed towards the upper portion of the LED 14, along a second path L₂. In a case of the second path L₂, the light may be emitted from the LED 14, and may be transmitted to an external environment through the transparent resin unit 15, as well.

Still another light may be directed towards the lower portion of the LED 14, be reflected by the bottom surface of the cavity 11a, be absorbed into the inner portion of the LED 14, and vanish, along a third path L₃. In a case of the third path L₃, the corresponding light may fail to be transmitted to the external environment. Accordingly, this may decrease in a light extraction efficiency of the LED package 10.

Also, since the light absorbed into the inner portion of the LED 14 may be converted into heat, thereby increasing a temperature of the LED 14. The increase in the temperature may result in a deterioration of the LED 14, and a reduction of an operational property and a lifespan of the LED 14.

### SUMMARY

One or more exemplary embodiments provide an LED package and a manufacturing method thereof, the LED package in which an LED may be disposed so that a direction of laminating a transparent substrate, a first semiconductor layer, an active layer, and a second semiconductor layer of an LED may be parallel to a bottom surface of a cavity.

One or more exemplary also provide an LED package and a manufacturing method thereof, the LED package in which an LED may be disposed to be inclined on a bottom surface of a cavity.

According to an aspect of an exemplary embodiment, there is provided an LED package including a package body comprising a cavity; a first lead frame and a second lead frame that are disposed in the cavity of the package body; and an LED mounted on a bottom surface of the cavity of the package body, the LED including a transparent substrate, a first semiconductor layer, an active layer, and a second semiconductor layer that are laminated sequentially in one of a first direction that is parallel to the bottom surface of the cavity and a second direction that is inclined with respect to the bottom surface of the cavity.

The LED may further include a first electrode formed on the first semiconductor layer exposed by a mesa structure, and a second electrode formed on the second semiconductor layer.

Each of the first lead frame and the second lead frame may extend from an external side of the package body into the cavity, and each of the first lead frame and the second lead frame may include a first end portion disposed on the bottom surface of the cavity in front of the first electrode and the second electrode, and a second end portion disposed at the external side of the package body.

The LED package may further include a plurality of wires to electrically connect the first lead frame and the first electrode, and to electrically connect the second lead frame and the second electrode.

The plurality of wires may have a bar structure to be connected, in a straight line, between the first lead frame and the first electrode, and between the second lead frame and the second electrode.

According to an aspect of another exemplary embodiment, there is provided an LED package including a package body including a cavity to expose a first lead frame and a second lead frame, and a groove on a bottom surface of the cavity, and an LED disposed to be inclined on the bottom surface of the cavity, and of which a part may be inserted in the groove.

The groove may include a first inclined surface, and a second inclined surface connected to the first inclined surface to be perpendicular to the first inclined surface.

The LED may include a transparent substrate, a first semiconductor layer, an active layer, and a second semiconductor layer that are laminated in a first direction, and the LED may be disposed such that a part of a side surface of the transparent substrate and a part of a lower surface of the transparent substrate may be bonded on the first inclined surface and the second inclined surface.

The LED may further include a first electrode formed on the first semiconductor layer exposed by a mesa structure, and a second electrode formed on the second semiconductor layer.

The first lead frame and the second lead frame may be disposed on the bottom surface of the cavity, and each may include one end disposed in front of the first electrode and the second electrode, and another end extending from the one end to an external side of the package body.

The LED package may further include a plurality of wires to electrically connect the first lead frame and the first electrode, and to electrically connect the second lead frame and the second electrode.

The LED package may further include a first light reflecting layer disposed on an inner side surface of the cavity, and a second light reflecting layer disposed on the bottom surface of the cavity including the groove, and disposed to be separate from the first lead frame and the second lead frame.

According to an aspect of another exemplary embodiment, there is also provided a method of manufacturing an LED package, the method including preparing a package body including a cavity in which a first lead frame and a second lead frame are disposed; and mounting an LED on a bottom surface of the cavity of the package body, the LED including a transparent substrate, a first semiconductor layer, an active layer, and a second semiconductor layer that are laminated sequentially in a first direction that is parallel to the bottom surface of the cavity.

The LED may further include a first electrode formed on the first semiconductor layer exposed by a mesa structure, and a second electrode formed on the second semiconductor layer. The first lead frame and the second lead frame may be disposed on the bottom surface of the cavity, and each may include one end disposed in front of the first electrode and the second electrode, and another end extending from the one end to an external side of the package body.

The method may further include electrically connecting the first lead frame and the first electrode, and electrically connecting the second lead frame and the second electrode, using a plurality of wires.

### BRIEF DESCRIPTION OF THE DRAWINGS

The above and/or other aspects, features, and advantages will become apparent and more readily appreciated from the following description of exemplary embodiments, taken in conjunction with the accompanying drawings of which:

FIG. 1 is a cross-sectional view of a structure of an LED package according to the related art;

FIGS. 2 and 3 area perspective view and a cross-sectional view of an LED package according to an exemplary embodiment;

FIG. 4 is a cross-sectional view of a structure of an LED package according to another exemplary embodiment; and

FIGS. 5 through 7 are cross-sectional views to describe a method of manufacturing an LED package according to an exemplary embodiment.

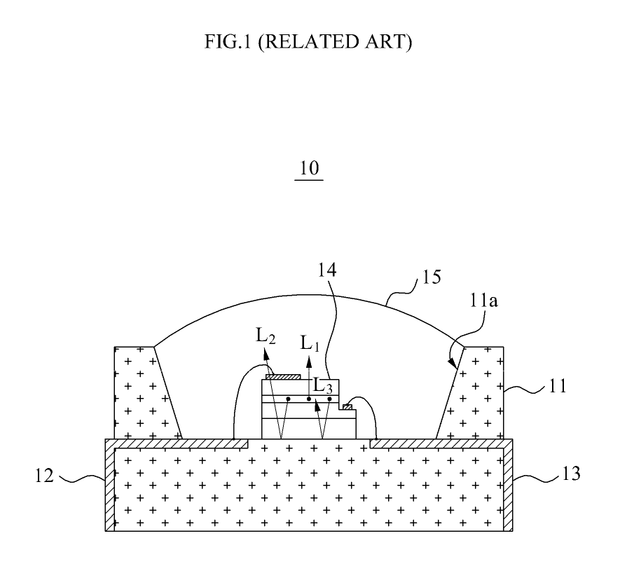

### DETAILED DESCRIPTION

Reference will now be made in detail to exemplary embodiments which are illustrated in the accompanying drawings, wherein like reference numerals refer to the like elements throughout. Exemplary embodiments are described below to explain the inventive concept by referring to the figures.

Where a detailed description is related to a related known function or configuration which may make the purpose of the exemplary embodiment unnecessarily ambiguous, such detailed description will be omitted. Also, terminologies used herein are defined to appropriately describe the exemplary embodiments and thus may be changed depending on a user, the intent of an operator, or a custom. Accordingly, the terminologies must be defined based on the following overall description of this specification.

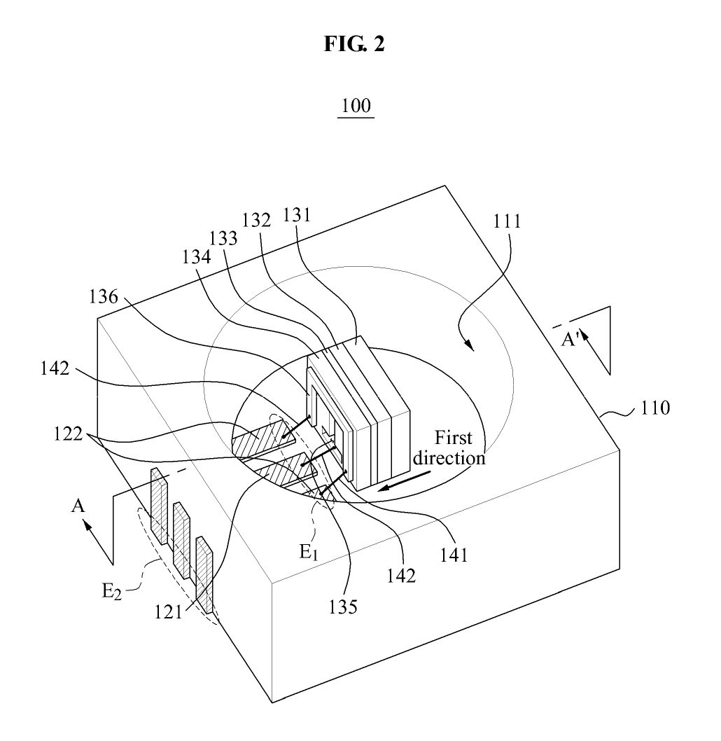

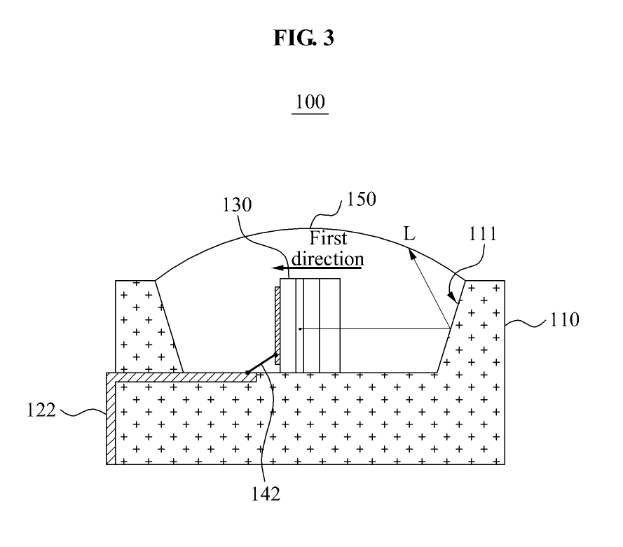

A structure of a light emitting device (LED) package 100 according to an exemplary embodiment will be described below with reference to FIGS. 2 and 3, wherein FIG. 2 is a perspective view of the LED package 100, and FIG. 3 is a cross-sectional view of the LED package 100.

The LED package 100 may include a package body 110, a first lead frame 121, a second lead frame 122, an LED 130, and a transparent resin unit 150. Although the transparent resin unit 150 is not illustrated in FIG. 2 for ease of description, the LED 100 may include the transparent resin unit 150 as illustrated in FIG. 3.

Referring to FIGS. 2 and 3, the package body 110 may include a cavity 111.

The LED 130 may include a transparent substrate 131, a first semiconductor layer 132, an active layer 133, and a second semiconductor layer 134. A portion of the first semiconductor layer 132 may be exposed by a mesa structure. Accordingly, the LED 130 may have a structure in which the first semiconductor layer 132 and the second semiconductor layer may be exposed.

The LED 130 may further include a first electrode 135 formed on the first semiconductor layer 132, and a second electrode 136 formed on the second semiconductor layer 134.

The LED 130 may be mounted in the package body 110 using a bonding material, for example, epoxy, a metallic bonding material, or the like. In particular, the LED 130 may be mounted in the package body 110 such that the transparent substrate 131, the first semiconductor layer 132, the active layer 133, and the second semiconductor layer 134 may be laminated sequentially in a first direction that is parallel to a bottom surface of the cavity 111.

That is, the LED 130 may be mounted in the package body 111 so that the transparent substrate 131, the first semiconductor layer 132, the active layer 133, and the second semiconductor layer 134 may be mounted in an upright standing orientation that is perpendicular to the bottom surface of the cavity 111. By way of the mounting structure, the LED 130 may emit light through both a side of the transparent substrate 131 and a side of the second semiconductor layer 134. In particular, since an electrode is not disposed on the surface of the transparent substrate 131, the light may be emitted through an entire surface of the transparent substrate 131.

Referring to FIG. 3, a light emitted through the entire surface of the transparent substrate 131 may be reflected by an inner side surface of the cavity 111, and may be transmitted to an external environment, along a path L. When the light is emitted through the transparent substrate 131 and the second semiconductor layer 134, rather than being absorbed into an inner portion of the LED 130 and vanishing, a light extraction efficiency of the LED package 100 may be improved.

Also, since the light is not be absorbed into the inner portion of the LED 130, a temperature of the LED 130 may be reduced. By reducing the temperature, a deterioration of the LED 130 may be prevented, and an operational property may be improved and a lifespan of the LED 130 may be increased.

The first lead frame 121 and the second lead frame 122 may be inserted in the package body 110, and may be exposed through the cavity 111. The first lead frame 121 and the second lead frame 122 may be disposed on the bottom surface of the cavity 111, and each may include an first end portion E₁ disposed in front of the first electrode 135 and the second electrode 136, and a second end portion E₂ extending from the first end portion E₁ to an external side of the package body 110.

A first wire 141 may electrically connect the first lead frame 121 and the first electrode 135, and a second wire 142 may electrically connect the second lead frame 122 and the second electrode 136.

In order to prevent a path of light from being changed by the first wire 141 and the second wire 142, the first wire 141 and the second wire 142 may be connected to the first electrode 131 and the second electrode 132 at regions close to a lower portion of the LED 130.

The first wire 141 may have a bar structure that is connected, in a straight line, between the first lead frame 121 and the first electrode 135, and the second wire 142 may have a bar structure that is connected, in a straight line, between the second lead frame 122 and the second electrode 136.

The first wire 141 and the second wire 142 may be formed of gold (Au). Also, the first wire 141 and the second wire 142 may have a thickness or a diameter corresponding to a range of about 50 micrometers (μm) to 200 μm to connect each lead frame and each electrode in a straight line, without bending.

The transparent resin unit 150 may be formed in the cavity 111 to protect the LED 130 from an external environment. The transparent resin unit 150 may be formed of an epoxy resin or a silicone resin, and may include a phosphor particle for converting a wavelength of the light generated from the LED 130.

The LED package 100 may further include a light reflecting layer on the inner side surface of the cavity 111 to reflect the light emitted through both sides of the LED 130 so that the light is transmitted to the external environment. The light reflecting layer may be formed of a metallic material having high reflectivity.

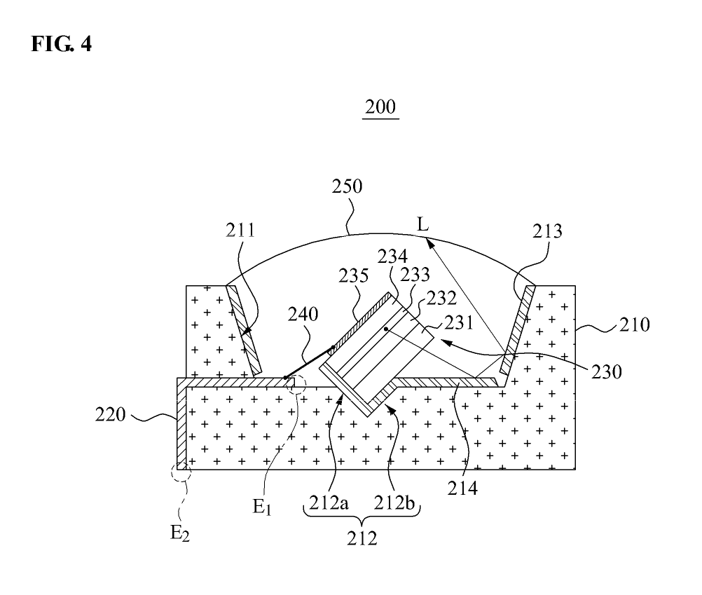

FIG. 4 is a cross-sectional view of a structure of an LED package 200 according to another exemplary embodiment. Referring to FIG. 4, the LED package 200 may include a package body 210, a lead frame 220, an LED 230, a wire 240, and a transparent resin unit 250.

The package body 210 may include a cavity 211. A bottom surface of the cavity 211 of package body 210 may include a recessed portion or groove 212 in which the LED 230 is inserted.

The package body 210 may further include a first light reflecting layer 213 disposed on an inner side surface of the cavity 211, and a second light reflecting layer 214 disposed on a bottom surface of the cavity 211 including the groove 212 and separated from the lead frame 220.

The LED 230 may include a transparent substrate 231, a first semiconductor layer 232, an active layer 233, and a second semiconductor layer 234. A part of the first semiconductor layer 232 may be exposed by a mesa structure.

Similar to the LED 130 of the exemplary embodiment shown in FIGS. 2 and 3, the LED 230 may further include a first electrode formed on the first semiconductor layer 232, and a second electrode 235 formed on the second semiconductor layer 234.

The LED 230 may be mounted in the package body 210 using a bonding material, for example, epoxy, a metallic boding material, and the like. In particular, a portion of the LED 230 may be disposed in the groove 212 so that the LED 230 is inclined with respect to the bottom surface of the cavity 211.

The groove 212 may include a first inclined surface 212a, and a second inclined surface 212b connected to the first inclined surface 212a to be perpendicular to the first inclined surface 212a. That is, the groove 212 may have a cross section of a V shape forming a right angle. The V shape of the groove 212 may have lateral symmetry based on a straight line perpendicular to the bottom surface of the cavity 211. That is, the first inclined surface 212a may have an inclination corresponding to −45° and the second inclined surface 212b may have an inclination corresponding to 45°, based on the straight line perpendicular to the bottom surface of the cavity 211, however, the exemplary embodiment is not be limited thereto. That is, the inclinations of the first inclined surface 212a and the second inclined surface 212b may be variable.

The LED 230 may be disposed such that a part of a side surface of the transparent substrate 231 and a part of a lower surface of the transparent substrate 231 may be bonded on the first inclined surface 212a and the second inclined surface 212b. Since the side surface and the lower surface of the transparent substrate 231 may form a right angle, the LED 230 may be inserted in the groove 212 easily.

When the LED 230 is disposed to be inclined on the bottom surface of the cavity 211, a surface of the transparent substrate 231 may float, rather than being bonded to the bottom surface of the cavity 211. Accordingly, the LED 230 may emit light through both a side of the transparent substrate 231 and a side of the second semiconductor layer 234.

The light emitted through the transparent substrate 231 and the second semiconductor layer 234 may be reflected by the first light reflecting layer 213 and the second light reflecting layer 214, and may be transmitted to an external environment.

As illustrated in FIG. 4, a light generated by the LED 230 may be emitted through the transparent substrate 231, be reflected primarily by the second light reflecting layer 214 and secondarily by the first light reflecting layer 213, and be transmitted to the external environment, along a path L.

The first light reflecting layer 213 and the second light reflecting layer 214 may be formed of a metallic material of high reflection, for example, aluminum (Al), silver (Ag), chromium (Cr), nickel (Ni), copper (Cu), and the like.

By the mounting structure of the LED 230, and elements of the first light reflecting layer 213 and the second light reflecting layer 214, the light may be emitted through the transparent substrate 231 and the second semiconductor layer 234, rather than being absorbed into an inner portion of the LED 230 and vanishing. As a result, a light transmission efficiency of the LED package 200 may be improved.

Also, since the light may not be absorbed into the inner portion of the LED 230, a temperature of the LED 230 may be reduced. By reducing the temperature, a deterioration of the LED 230 may be prevented, and an operational property may be improved and a lifespan of the LED 230 may be increased.

The lead frame 220 may be inserted in the package body 210, and may be exposed through the cavity 211. Also, the lead frame 220 may be disposed on the bottom surface of the cavity 211, and may include a first end portion E₁ disposed in front of the second electrode 235, and a second end portion E₂ extending from the first end portion E₁ to an external side of the package body 210.

The wire 240 may electrically connect the lead frame 220 and the second electrode 235.

In order to prevent a path of light from being changed by the wire 240, the wire 240 may be connected to the second electrode 235 at a region close to a lower portion of the LED 230.

The wire 240 may have a bar structure that is connected, in a straight line, between the lead frame 220 and the second electrode 235. The wire 240 may be formed of Au. Also, the wire 240 may have a thickness or a diameter corresponding to a range of about 50 μm to 200 μm to connect the lead frame 220 and the second electrode 235 in a straight line, without bending.

The transparent resin unit 250 may be formed in the cavity 211 to protect the LED 230 from an external environment. The transparent resin unit 250 may be formed of an epoxy resin or a silicone resin, and may include a phosphor particle for converting a wavelength of the light generated from the LED 230.

Similar to the LED 130 of the exemplary embodiment shown in FIGS. 2 and 3, the LED 230 may further include a first electrode formed on the first semiconductor layer 232, and the LED package 200 may further include a lead frame electrically connected with the first electrode through a wire.

FIGS. 5 through 7 are cross-sectional views to describe a method of manufacturing an LED package according to an exemplary embodiment.

Referring to FIG. 5, the method may include a process of providing a package body 310 including a cavity 311. The package body 310 may have a structure in which a first lead frame 320 may be inserted, and may be exposed through the cavity 311.

The package body 310 may include a second lead frame disposed to be separate from the first lead frame 320, and exposed through the cavity 311. Structures of the first lead frame 320 and the second lead frame will be understood easily through the description provided with reference to FIG. 2. and thus, repeated descriptions will be omitted for conciseness.

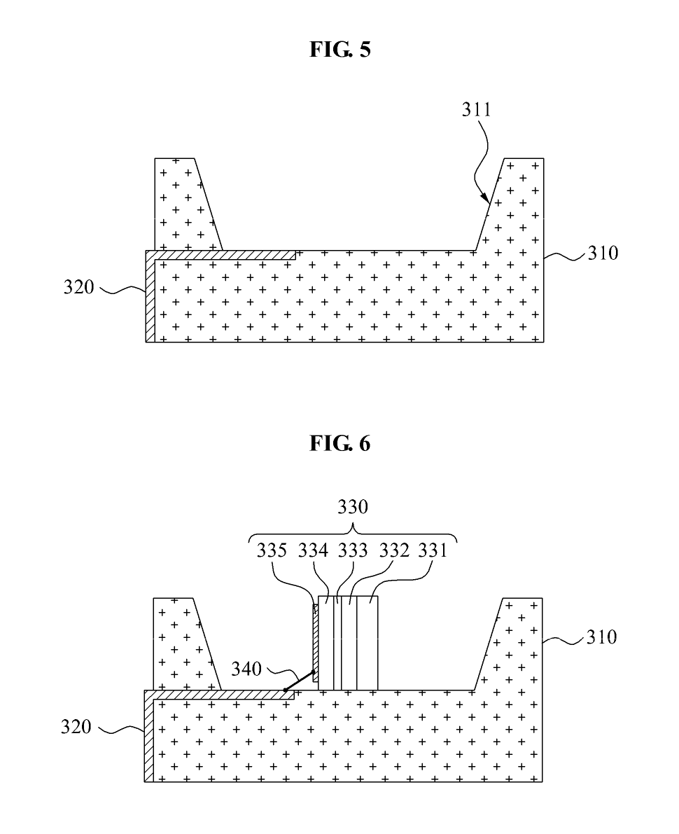

Referring to FIG. 6, the method may include a process of mounting an LED 330 in the cavity 311 of the package body 310. Here, the LED 330 may have a structure in which a transparent substrate 331, a first semiconductor layer 332, an active layer 333, and a second semiconductor layer 334 may be laminated in the first direction, sequentially so that a first direction may be parallel to a bottom surface of the cavity 311.

That is, the LED 330 may be mounted in the package body 311 so that the transparent substrate 331, the first semiconductor layer 332, the active layer 333, and the second semiconductor layer 334 may be perpendicular to the bottom surface of the cavity 311. By the mounding structure, the LED 330 may emit light through both a side of the transparent substrate 311 and a side of the second semiconductor layer 334.

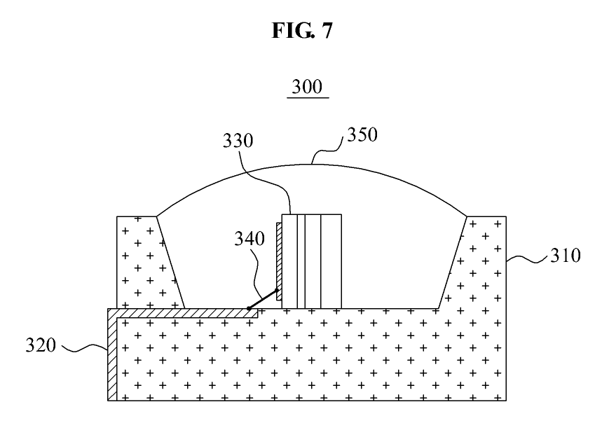

Referring to FIG. 7, the method may include a process of electrically connecting the first lead frame 320 and a second electrode 335 formed on the second semiconductor layer 334, using a wire 340. In this process, a method of connecting the first lead frame 320 and the second electrode 340 using Au having a thickness or a diameter corresponding to a range of about 50 μm to 200 μm may be used.

When the first lead frame 320 and the second electrode 340 are connected using the wire 340, a process of covering the LED 330 by filling an inner portion of the cavity 311 with a transparent resin, for example an epoxy resin, a silicone resin, and the like, may be performed additionally.

In an LED package and a manufacturing method thereof according to exemplary embodiments, an LED may be disposed so that a direction of laminating a transparent substrate, a first semiconductor layer, an active layer, and a second semiconductor layer may be parallel to a bottom surface of a cavity, or may be disposed to be inclined on the bottom surface of the cavity. By the disposing structure of the LED, light may be emitted through the transparent substrate, thereby a light extraction efficiency may be increased and a heat temperature may be reduced.

Although a few exemplary embodiments have been shown and described, the inventive concept is not limited to the described exemplary embodiments. Instead, it would be appreciated by those skilled in the art that changes may be made to these exemplary embodiments without departing from the principles and spirit of the inventive concept, the scope of which is defined by the claims and their equivalents.

What is claimed is:

1. A light emitting device (LED) package comprising:
a package body comprising a cavity;
a first lead frame and a second lead frame that are disposed in the cavity of the package body; and
an LED mounted on a bottom surface of the cavity of the package body, the LED comprising a transparent substrate, a first semiconductor layer, an active layer, and a second semiconductor layer that are laminated sequentially in one of a first direction that is parallel to the bottom surface of the cavity and a second direction that is inclined with respect to the bottom surface of the cavity.

2. The LED package of claim 1, wherein the LED further comprises:
a first electrode formed on the first semiconductor layer exposed by a mesa structure; and
a second electrode formed on the second semiconductor layer.

3. The LED package of claim 2, wherein each of the first lead frame and the second lead frame extends from an external side of the package body into the cavity, and each of the first lead frame and the second lead frame comprises a first end portion disposed on the bottom surface of the cavity in front of the first electrode and the second electrode, and a second end portion disposed at the external side of the package body.

4. The LED package of claim 3, further comprising:
a first wire that electrically connects the first end portion of the first lead frame to the first electrode; and
a second wire that electrically connects the first end port of the second lead frame to the second electrode.

5. The LED package of claim 4, wherein each of the first and second wires has a bar structure formed in a straight line.

6. The LED package of claim 1, wherein the bottom surface of the cavity includes a groove, and a portion of the LED is disposed in the groove such that the transparent substrate, the first semiconductor layer, the active layer, and the second semiconductor layer are laminated sequentially in the second direction that is inclined with respect to a plane of the bottom surface of the cavity.

7. The LED package of claim 6, wherein the groove comprises a first inclined surface, and a second inclined surface adjacent to and perpendicular to the first inclined surface.

8. The LED package of claim 7, wherein the LED is disposed such that a part of a side surface of the transparent substrate and a part of a lower surface of the transparent substrate are bonded on the first inclined surface and the second inclined surface, respectively.

9. The LED package of claim 8, wherein the LED further comprises:
a first electrode formed on the first semiconductor layer exposed by a mesa structure; and
a second electrode formed on the second semiconductor layer.

10. The LED package of claim 9, wherein each of the first lead frame and the second lead frame extends from an external side of the package body into the cavity, and each of the first lead frame and the second lead frame comprises a first end portion disposed on the bottom surface of the cavity in front of the first electrode and the second electrode, and a second end portion disposed at the external side of the package body.

11. The LED package of claim 10, further comprising:
a first wire that electrically connects the first end portion of the first lead frame to the first electrode; and
a second wire that electrically connects the first end port of the second lead frame to the second electrode.

12. The LED package of claim 6, further comprising:
a first light reflecting layer disposed on an inner side surface of the cavity; and
a second light reflecting layer disposed on the bottom surface of the cavity including the groove, and separated from the first lead frame and the second lead frame.

13. A method of manufacturing a light emitting device (LED) package, the method comprising:
preparing a package body comprising a cavity in which a first lead frame and a second lead frame are disposed; and
mounting an LED on a bottom surface of the cavity of the package body, the LED comprising a transparent substrate, a first semiconductor layer, an active layer, and a second semiconductor layer that are laminated sequentially in a first direction that is parallel to the bottom surface of the cavity.

14. The method of claim 13, wherein:
the LED further comprises a first electrode formed on the first semiconductor layer exposed by a mesa structure, and a second electrode formed on the second semiconductor layer, and
each of the first lead frame and the second lead frame extends from an external side of the package body into the cavity, and each of the first lead frame and the second lead frame comprises a first end portion disposed on the bottom surface of the cavity in front of the first electrode and the second electrode, and a second end portion disposed at the external side of the package body.

15. The method of claim 14, further comprising:
electrically connecting the first lead frame and the first electrode via a first wire, and electrically connecting the second lead frame and the second electrode via a second wire.

16. A light emitting device (LED) package comprising:
a package body comprising a cavity; and
an LED comprising a transparent substrate, a first semiconductor layer, an active layer, and a second semiconductor layer that are laminated sequentially and disposed on a bottom surface of the cavity in one of an upright standing orientation with respect to the bottom surface of the cavity body and an inclined orientation with respect to the bottom surface of the cavity.

17. The LED package of claim 16 further comprising:
a first lead frame and a second lead frame that are disposed in the cavity of the package body;
a first electrode formed on the first semiconductor layer exposed by a mesa structure; and
a second electrode formed on the second semiconductor layer.

18. The LED package of claim 17, wherein each of the first lead frame and the second lead frame extends from an external side of the package body into the cavity, and each of the first lead frame and the second lead frame comprises a first end portion disposed on the bottom surface of the cavity in front of the first electrode and the second electrode, and a second end portion disposed at the external side of the package body.

19. The LED package of claim 16, wherein the bottom surface of the cavity includes a groove, and a portion of the LED is disposed in the groove such that the transparent substrate, the first semiconductor layer, the active layer, and the second semiconductor layer are arranged in the inclined orientation with respect to the bottom surface of the cavity.

20. The LED package of claim 19, wherein the groove comprises a first inclined surface, and a second inclined surface that is adjacent to and perpendicular to the first inclined surface.
